(19) United States
(12) Patent Application Publication
(10) Pub. No.: US 2010/0274508 A1
(43) Pub. Date: Oct. 28, 2010

(54) Mobile Electronic Device and Method for Controlling the Same

(75) Inventors: Akira Koyama, Kanagawa (JP); Takanobu Hayakawa, Kanagawa (JP); Masayoshi Nakajima, Kanagawa (JP)

Correspondence Address: PROCOPIO, CORY, HARGREAVES & SAVITCH LLP, 525 B STREET, SUITE 2200, SAN DIEGO, CA, 92101, US

(73) Assignee: KYOCERA CORPORATION, Kyoto (JP)

(21) Appl. No.: 12/810,745

(22) PCT Filed: Dec. 27, 2007
(86) PCT No.: PCT/JP2008/073853

§ 371 Date: Jun. 25, 2010

(30) Foreign Application Priority Data
Dec. 27, 2007 (JP) JP2007-336659

(51) Int. Cl. G01R 31/36

(52) U.S. Cl. 702/63

(57) ABSTRACT

It is possible to provide a mobile electronic device which can accurately and clearly display a cell service life and a method for controlling the device.

The mobile electronic device includes: a charge cell (32); a voltage measuring unit (system IC 64) which is connected to the charge cell (32) and measures a voltage of the charge cell (32); an output unit (display 21) which outputs various information; a memory (63) which stores a weighting value for each of voltage values; and a control unit (system IC 64) which measures a voltage of the charge cell (32) by the voltage measuring unit upon each start and end of charge of the charge cell (32), extracts a weighting value corresponding to the measured voltage value from the memory (63), successively adds the extracted weighting values so as to identify information on a number of charge times, and stores the information in the memory (63). The control unit causes the output unit to output information on a service life of the charge cell (32) according to the information on the number of charge times stored in the memory (63).

### TECHNICAL FIELD

The present invention relates to a portable electronic device to which a rechargeable battery is mounted, and particularly relates to a portable electronic device that outputs information on life of a rechargeable battery, and a method of controlling the same.

### BACKGROUND ART

Although lithium ion batteries are the current mainstream of batteries for cellular phones, due to the ever-increasing trend toward smaller sizes, lighter weight and higher functionality of mobile terminal devices (such as for continuously viewing a digital television program, continuously playing music, browsing WEB sites, etc.), it is anticipated that the cycle of charging and discharging a battery will be accelerated, and as a result, the life of a battery will tend to be shortened relative to the period of use of a mobile terminal device.

Here, methods of detecting the life of a battery include a method in which the life of a battery is determined by way of a change in an impedance value of the battery (for example, see Patent Document 1), and a method in which a function regarding a charging/discharging curve is stored in advance, and the life of a battery is determined by calculating and weighting a deterioration value when charging and discharging (for example, see Patent Document 2).

Moreover, in general, the life of a battery is defined by each battery manufacturer, and refers to a state in which the capacitance has been decreased to about 50 to 60% of the initial capacitance due to, for example, about 500 to 600 times charging and discharging. In addition, beyond this state, the expected operation of the mobile terminal device cannot be guaranteed due to an increase of internal resistance, etc.

Therefore, it is necessary to accurately and clearly output the life of a battery to the user in order to guarantee expected operations of the mobile terminal device.

Patent Document 1: Japanese Unexamined Patent Application, First Publication No. H05-74501

Patent Document 2: Japanese Unexamined Patent Application, First Publication No. 2004-264303

### DISCLOSURE OF THE INVENTION

### Problems to be Solved by the Invention

Incidentally, although Patent Document 1 has proposed a method in which the number of cycles is converted from a state of internal impedance to derive a life, a mobile terminal device does not have a circuit to measure an electric current in many cases, and it is difficult to perform such complicated control.

Furthermore, Patent Document 2 has proposed a method in which deterioration of a battery is displayed based on a degree of deterioration that varies depending on weighting of charging and discharging. However, a specific system configuration and a detection method are not described therein, and thus it is difficult to accurately and clearly output the life of a battery to the user in order to guarantee expected operations of the mobile terminal device.

Even by diverting the techniques proposed in those Patent Documents, it may be considered difficult to accurately and clearly display the life of a battery of a mobile terminal device.

Moreover, in a case in which the life of a battery of a mobile terminal device cannot be accurately and clearly displayed, the user oneself will determine the life of the battery, and such a way of using the mobile terminal device is not comfortable.

The present invention has been made in view of the aforementioned problems, and an object thereof is to provide a mobile electronic device and a method for controlling the same, which are capable of accurately and clearly displaying the life of a battery, by way of a simple configuration without increasing the cost.

### Means for Solving the Problems

In order to solve the abovementioned problems, a portable electronic device according to the present invention is characterized by including: an output unit that outputs a variety of information; a storage unit that stores a weighting value for each voltage value; a voltage measuring unit that measures, each time charging of a rechargeable battery that is mounted occurs, a voltage of the rechargeable battery; and a control unit that extracts from the storage unit a weighting value corresponding to a voltage value measured via the voltage measuring unit, and that sequentially adds the weighting value thus extracted, thereby identifying information on a number of times charging, and storing the information in the storage unit, in which the control unit causes the output unit to output information on life of the rechargeable battery, based on the information on the number of times charging stored in the storage unit.

Moreover, in the portable electronic device, it is preferable that the control unit measures, each time charging of the rechargeable battery is completed, a voltage of the rechargeable battery via the voltage measuring unit.

In addition, in the portable electronic device, it is preferable that the control unit measures, each time charging of the rechargeable battery is started, a voltage of the rechargeable battery via the voltage measuring unit.

Furthermore, in the portable electronic device, it is preferable that the weighting value corresponds to a large value when the voltage value is close to a full charge value, and the weighting value corresponds to a small value when the voltage value is close to a minimum operational voltage value.

Moreover, in the portable electronic device, it is preferable that the storage unit stores a predetermined value for indicating that the life of the rechargeable battery has reached an end, and the control unit identifies information on the life, based on a remaining level in the information on the number of times charging relative to the predetermined value.

In addition, in the portable electronic device, it is preferable that the control unit identifies information on the life as a remaining number of times for which charging is possible.

Furthermore, in the portable electronic device, it is preferable that the control unit detects a connection state of a charger that charges the rechargeable battery, and detects that the rechargeable battery has been mounted to the charger or that the rechargeable battery has been removed from the charger, based on the connection state, thereby determining that charging of the rechargeable battery has been started or completed.

Moreover, in the portable electronic device, it is preferable that the output unit includes a display unit that displays the information on life of the rechargeable battery, based on the information on the number of times charging.

In addition, it is preferable that the portable electronic device further includes an operation unit that requests, by way of a predetermined operation, the control unit to initialize the information on the number of times charging stored in the storage unit, in which the storage unit includes an area that is not initialized, and when an initialization request is performed by the operation unit, the control unit copies information, which is identical with the information on the number of times charging, into the area that is not initialized, and then initializes a display of the information on the life.

Furthermore, in the portable electronic device, it is preferable that the storage unit stores a predetermined value for indicating that the life of the rechargeable battery has reached an end, and the control unit identifies information on the life, based on a remaining level in the information on the number of times charging relative to the predetermined value.

Moreover, in the portable electronic device, it is preferable that the control unit identifies information on the life as a remaining number of times for which charging is possible.

In addition, in the portable electronic device, it is preferable that the control unit detects a connection state of a charger that charges the rechargeable battery, and detects that the rechargeable battery has been mounted to the charger or that the rechargeable battery has been removed from the charger, based on the connection state, thereby determining that charging of the rechargeable battery has been started or completed.

Furthermore, in the portable electronic device, it is preferable that the output unit includes a display unit that displays the information on life of the rechargeable battery, based on the information on the number of times charging.

Moreover, it is preferable that the portable electronic device further includes an operation unit that requests, by way of a predetermined operation, the control unit to initialize the information on the number of times charging stored in the storage unit, in which the storage unit includes an area that is not initialized, and when an initialization request is performed by the operation unit, the control unit copies information, which is identical with the information on the number of times charging, into the area that is not initialized, and then initializes a display of the information on the life.

In order to solve the abovementioned problems, a control method in a portable electronic device including a rechargeable battery, an output unit and a storage unit is characterized by including the steps of: measuring, each time charging of the rechargeable battery is started or completed, a voltage of the rechargeable battery; extracting, from the storage unit, a weighting value corresponding to a voltage value thus measured; sequentially adding the weighting value thus extracted; identifying information on a number of times charging based on the weighting value thus added; and storing the information in the storage unit, and causing the output unit to output information on life of the rechargeable battery, based on the information on the number of times charging stored in the storage unit.

### Effects of the Invention

According to the present invention, the life of a battery can be accurately and clearly displayed.

### BRIEF DESCRIPTION OF THE DRAWINGS

FIG. 1 is a perspective view showing an appearance of a cellular telephone device according to the present invention;

FIG. 2 is a perspective view showing a configuration of an operation unit side body included in the cellular telephone device according to the present invention;

FIG. 3 is graph showing a relationship between a number of cycles and a discharging capacitance rate of a rechargeable battery;

FIG. 4 is a block diagram showing features of the cellular telephone device according to the present invention;

FIG. 5 is a graph showing a relationship between a discharging voltage and a capacitance rate to be utilized when determining a first weighting coefficient;

FIG. 6 is a graph showing a relationship between a charging voltage and a charging rate to be utilized when determining a second weighting coefficient;

FIG. 7 is a graph illustrating counting of the number of times for the life of the rechargeable battery;

FIG. 8 is a first flowchart illustrating a method of counting the number of cycles the rechargeable battery has been charged and discharged, and a method of outputting life of the rechargeable battery;

FIG. 9 is a second flowchart illustrating the method of counting the number of cycles the rechargeable battery has been charged and discharged, and the method of outputting life of the rechargeable battery;

FIG. 10 is a diagram showing a display screen displayed on a display when confirming initial setting;

FIG. 11 is a diagram showing a display screen displayed on the display in a case in which it has been determined that there has been an initialization request of a cycle count;

FIG. 12 is a diagram showing a display screen displayed on the display in a case in which a cycle count number has been added into a third area;

FIG. 13 is a diagram showing an aspect when information on a deterioration state (battery life) is displayed on the display; and

FIG. 14 is a diagram showing an aspect when information for prompting replacement of the rechargeable battery is displayed on the display.

### EXPLANATION OF REFERENCE SYMBOLS

1 cellular telephone device

11 operation key set

21 display (output unit)

22 sound output unit (output unit)

32 rechargeable battery

60 transmission and reception processing block

61 external power source connection unit

62 switch unit

63 memory

64 system IC (control unit, voltage measuring unit)

70 main antenna

100 charger

### PREFERRED MODE FOR CARRYING OUT THE INVENTION

A description is provided hereinafter regarding an embodiment of the present invention.

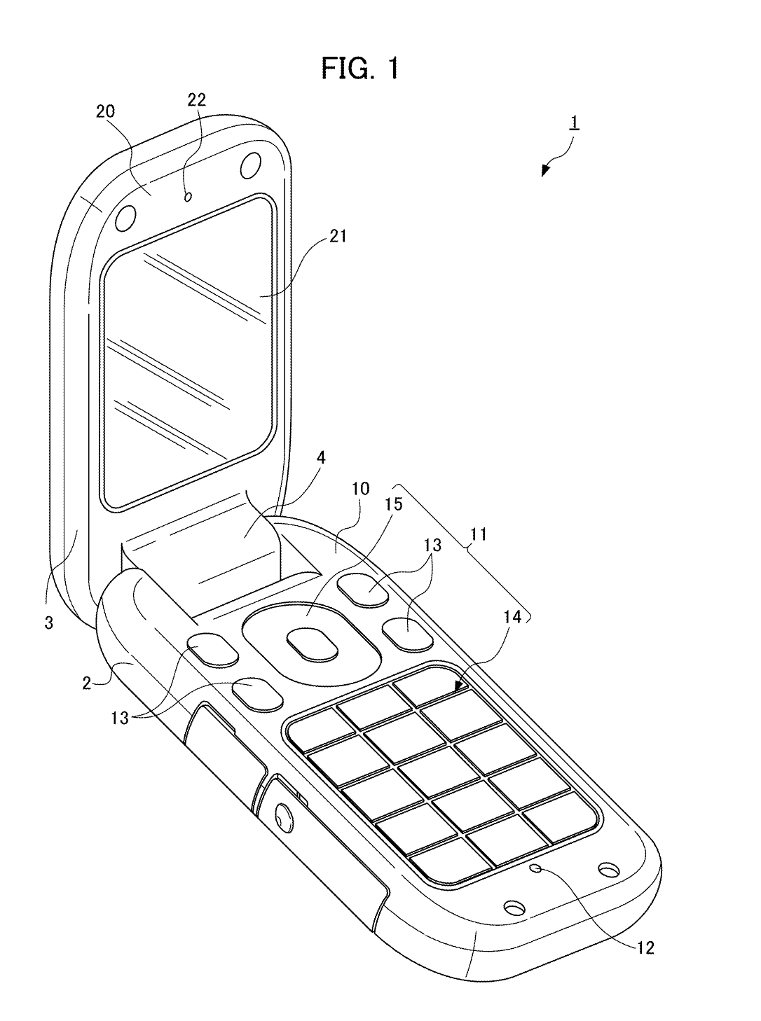

FIG. 1 is a perspective view showing an appearance of a cellular telephone device 1 as an example of a portable electronic device according to the present invention. It should be noted that, although a cellular telephone device is described hereinafter, the present invention is not limited thereto, and may be a PHS (Personal Handyphone System), a PDA (Personal Digital Assistant), a portable navigation device, a notebook PC or the like.

The cellular telephone device 1 is configured to include an operation unit side body 2 and a display unit side body 3. The operation unit side body 2 is configured to include on a front face 10 thereof an operation button set 11 and a microphone 12 to which sounds, which a user of the cellular telephone device 1 produces during a phone call, are input. The operation key set 11 includes: feature setting operation buttons 13 for operating various settings and various features such as a telephone number directory feature and a mail feature; input operation buttons 14 for inputting digits of a telephone number and characters for mail; and a selection operation button 15 that performs selection of the various operations and scrolling.

The display unit side body 3 is configured to include, on a front face portion 20, a display 21 for displaying a variety of information, and a sound output unit 22 for outputting sound of the other party of the conversation.

An upper end portion of the operation unit side body 2 and a lower end portion of the display unit side body 3 are connected via a hinge mechanism 4. The cellular telephone device 1 can be in a state where the operation unit side body 2 and the display unit side body 3 are apart from each other (opened state), and in a state where the operation unit side body 2 and the display unit side body 3 are contacting each other (folded state), as the operation unit side body 2 and the display unit side body 3, connected via the hinge mechanism 4, pivot with respect to each other.

It should be noted that, although FIG. 1 shows a so-called flip-type cellular telephone device, the present invention is not limited thereto, and the cellular telephone device 1 may be of: a slider type in which one body slides to one direction from a state in which the operation unit side body 2 and the display unit side body 3 are mutually superimposed; or a rotating type (turning type) in which one body is rotated around an axis line along the direction in which the operation unit side body 2 and the display unit side body 3 are superimposed.

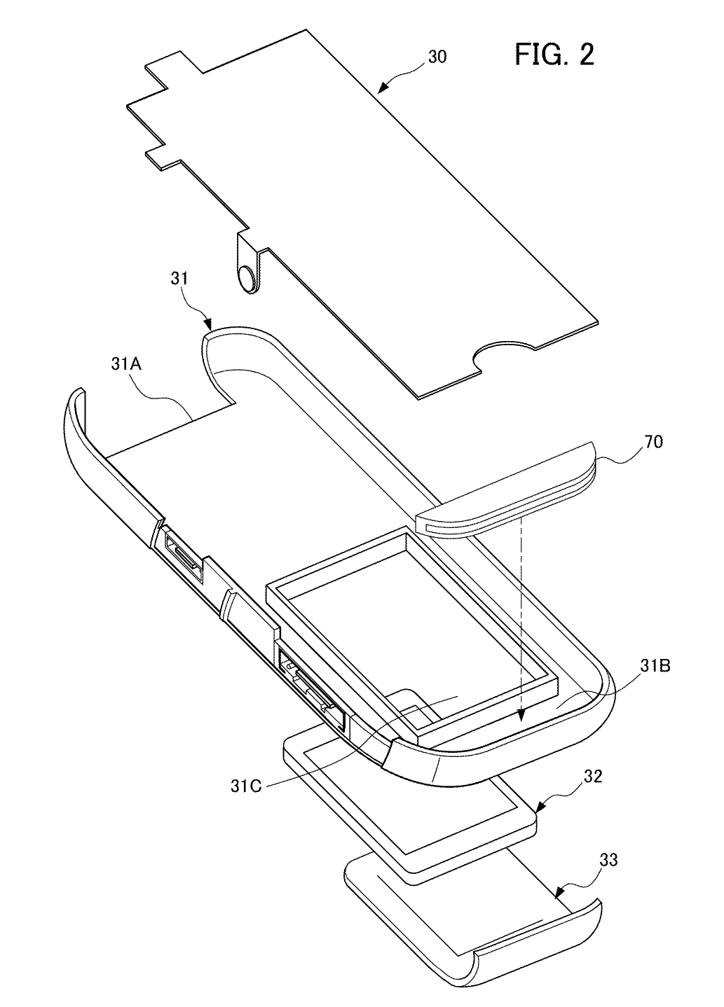

In addition, FIG. 2 is an exploded perspective view of a part of the operating unit side body 2. As shown in FIG. 2, the operation unit side body 2 is composed of a circuit board 30, a rear case portion 31, a rechargeable battery 32 that is a rechargeable cell, and a rechargeable-battery cover 33.

On the circuit board 30, an element such as a CPU (corresponding to a system IC 64 to be described later) that performs predetermined arithmetic processing is mounted, and a predetermined signal is transmitted to the CPU when the user operates the operation key set 11 on the front portion 10. Moreover, battery terminals are mounted on the circuit board 30.

The rear case portion 31 includes: a hinge mechanism fixing portion 31A that fixes the hinge mechanism 4; a main antenna housing portion 31B that houses a main antenna 70 which communicates using a predetermined usable frequency band; and a rechargeable-battery housing portion 31C that houses the rechargeable battery 32.

### <Characteristics of Rechargeable Battery 32>

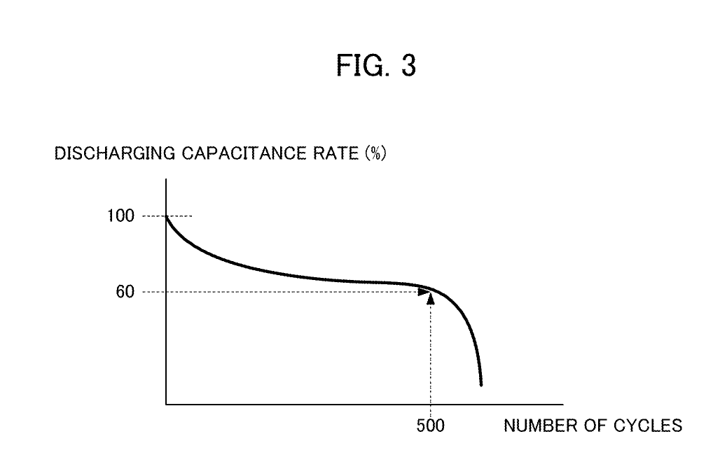

Here, characteristics of the rechargeable battery 32 are described. For example, in a case in which the rechargeable battery 32 is a lithium ion battery, generally, the capacitance is decreased to approximately around 60% due to approximately around 500 cycles of charging/discharging operations. Moreover, a state in which the capacitance is decreased to approximately around 60% is referred to as a state in which the life of the rechargeable battery has reached an end. It should be noted that the rechargeable battery 32 is still usable even in the state in which the life of the rechargeable battery has reached the end; however, in such a state, the impedance has also increased, and thus it is difficult to achieve the desired performance. In addition, after the capacitance has fallen below approximately 60%, the capacitance will decrease at an accelerated pace (see FIG. 3).

Accordingly, although it is desirable to count the number of times the rechargeable battery 32 has been charged and discharged, and to output the life of the rechargeable battery to the user in accordance with the count, if a circuit for counting the number of times the rechargeable battery 32 has been charged and discharged is newly added, the cost will increase. Therefore, according to the present invention, a configuration and a method are proposed in which the number of times the rechargeable battery 32 has been charged and discharged is easily counted without newly adding a circuit, and the life of the rechargeable battery 32 is accurately and clearly output to the user in accordance with this count.

### <Functional Block of Cellular Telephone Device 1>

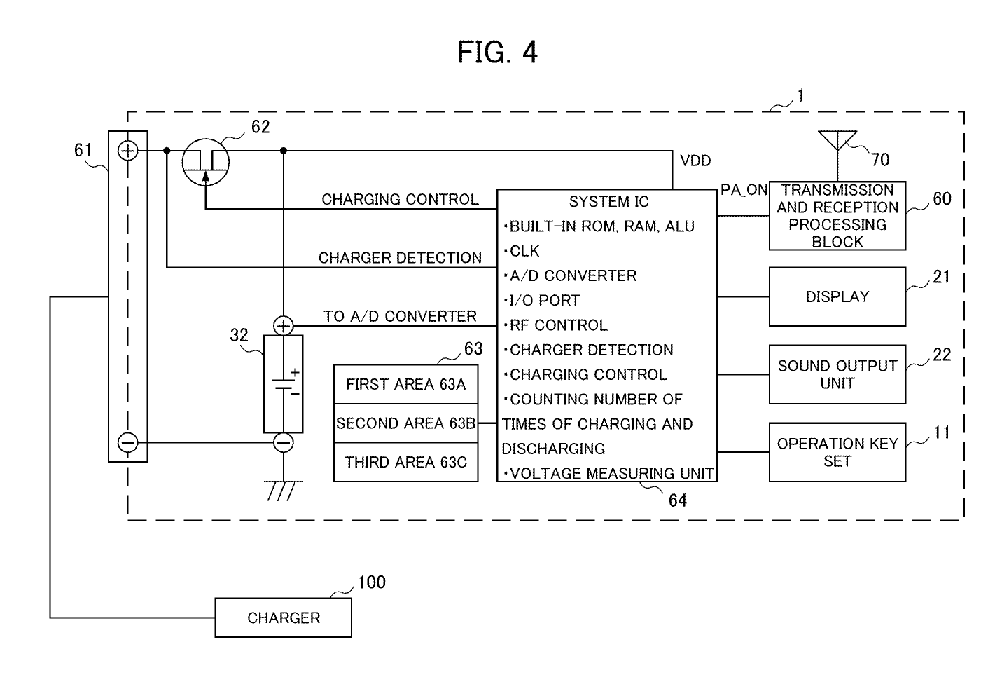

FIG. 4 is a functional block diagram showing features of the cellular telephone device 1. As shown in FIG. 4, the cellular telephone device 1 includes: the main antenna 70; a transmission and reception processing block 60 connected to the main antenna 70; the display 21 (output unit) that displays a variety of information; the sound output unit 22 (output unit) that outputs sound of the other party of the conversation; an external power source connection unit 61 that is connected to an AC adapter which is connected to a commercial power supply; a switch unit 62 connected to the external power source connection unit 61; memory 63; the system IC 64 (control unit, voltage measuring unit); the rechargeable battery 32; and the operation key set 11.

The main antenna 70 communicates with external devices (base stations) by using a predetermined usable frequency band (for example, 800 MHz). It should be noted that, although the predetermined usable frequency band is set to 800 MHz in the present embodiment, other frequency bands can also be used. Moreover, the main antenna 70 can be configured as a so-called dual band compatible antenna that can accept, in addition to the predetermined usable frequency band, another usable frequency band (for example, 2 GHz), or as a multi-band compatible antenna that can further accept three or more usable frequency bands.

The transmission and reception processing block 60 amplifies a signal, which has been received via the main antenna 70, by a low noise amplifier, performs demodulation processing on the signal thus amplified, and transmits the signal thus processed to the system IC 64, and in addition, performs modulation processing on a signal transmitted from the system IC 64, amplifies the signal thus modulation-processed by a power amplifier, and transmits the signal thus amplified to an external device (base station) via the main antenna 70.

The display 21 and the sound output unit 22 serve as output units for visually and audibly outputting a variety of information to the user.

An AC adaptor (charger) 100, which converts an AC voltage supplied from a commercial power supply into a DC voltage, is connected to the external power source connection unit 61.

The switch unit 62 is configured, for example, with an FET, and is arranged between the external power source connection unit 61 and the system IC 64, in which the external power source connection unit 61 and the system IC 64 are switched into an electrical interruption (OFF) state or an electrical conduction (ON) state in accordance with a control signal (charging control signal) of the system IC 64.

The memory 63 is a nonvolatile memory medium, and for example, as shown in FIG. 4, the memory 63 is configured with: a first area 63A that is an area for storing a charging rate and a discharging rate; a second area 63B that is an area, into which a count value of a number of cycles (information on the number of times charging and discharging) is stored, and in which writing and erasing by the user operation are possible; and a third area 63C that is an area into which the count value of the number of cycles is stored, and in which erasing by the user operation is impossible. It should be noted that the third area 63C is an area that is configured such that the user is not allowed any access, but a shop (enterprise side) and the like are allowed to freely access.

The system IC 64 includes ROM, RAM, ALU (Arithmetic and Logic Unit), a clock signal generating unit, an analog-to-digital converter, a plurality of I/O ports, etc.

Moreover, the system IC 64 determines whether the charger 100 is connected to the external power source connection unit 61, and controls a switching operation of the switch unit 62 by way of a charging control signal. In addition, the system IC 64 has a function as a voltage measuring unit that performs voltage measurement of the rechargeable battery 32, and a function to count the number of times the rechargeable battery 32 has been charged and discharged.

Furthermore, the system IC 64 may also be configured such that, in a case in which an initialization request is performed via the operation key set 11, the same information as a count value of the number of cycles written in the second area 63B of the memory 63 is copied into the third area 63C that is an area which is not initialized, and displaying of life information is initialized.

Moreover, the system IC 64 is connected to the operation key set 11, and performs a predetermined operation in accordance with an operation signal transmitted from the operation key set 11.

Here, control according to the system IC 64 is described. Each time charging of the rechargeable battery 32 is started or completed, the system IC 64 measures a voltage of the rechargeable battery 32, and extracts a weighting value corresponding to the measured voltage value from the memory 63. In addition, the system IC 64 sequentially adds a weighting value thus extracted, thereby identifying information on the number of times charging and storing in the memory 63.

Furthermore, the system IC 43 causes the display 21 and/or the sound output unit 22 to output information on the life of the rechargeable battery 32, based on information on the number of times charging stored in the memory 63.

With such a configuration, it is possible to accurately and clearly present the life of the rechargeable battery 32 to the user with a simple configuration without increasing the cost.

Next, the function of the system IC 64 (function to count the number of times the rechargeable battery 32 has been charged and discharged) is described.

By measuring a voltage state of the rechargeable battery 32, the system IC 64 counts the number of cycles the rechargeable battery 32 has been charged and discharged. For example, when electrically connected to the charger 100, the system IC 64 measures a battery voltage of the rechargeable battery 32 before starting charging (a first weighting coefficient X according to deterioration is factored therein), thereby counting the number of times of discharging. Moreover, when electrically disconnected from the charger 100, the system IC 64 measures a battery voltage of the rechargeable battery 32 after completing the charging (a second weighting coefficient Y according to deterioration is factored therein), thereby counting the number of times charging.

Next, the first weighting coefficient X and the second weighting coefficient Y are described. It should be noted that the first weighting coefficient X and the second weighting coefficient Y are stored in a storage unit such as the memory 63, and are referred to when counting the number of times charging and discharging.

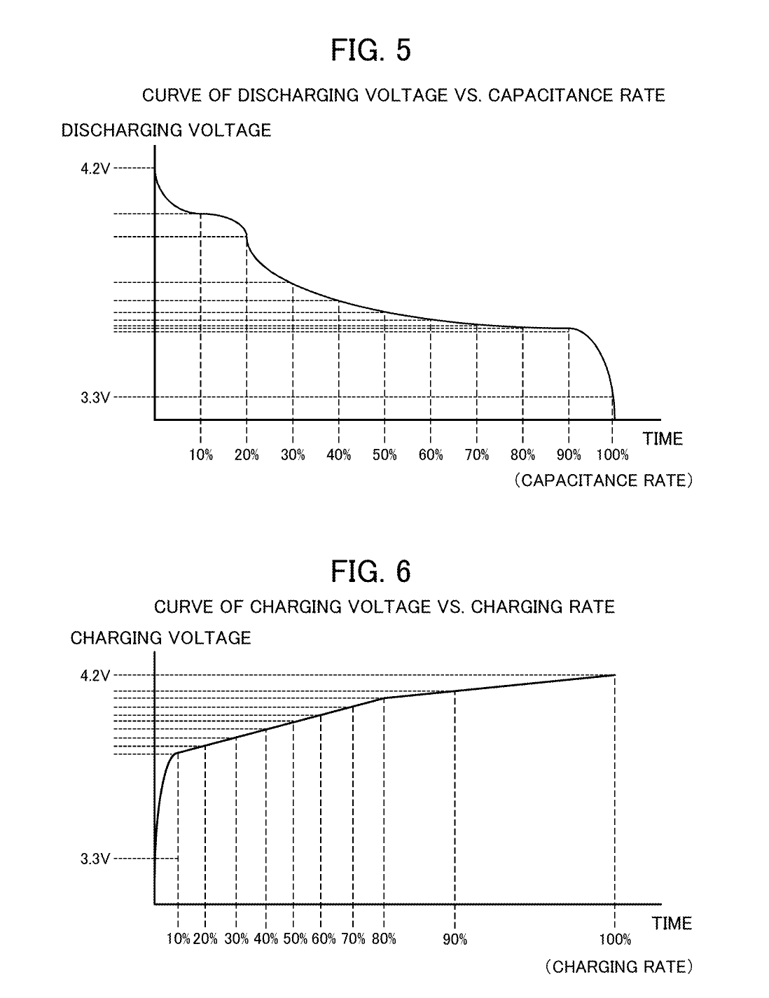

The first weighting coefficient X is determined, for example, in accordance with FIG. 5 as follows (a battery voltage immediately before starting charging→the first weighting coefficient X):

4.20 V or higher→0 time;

4.00 V→0.1 times;

3.88 V→0.2 times;

3.83 V→0.3 times;

3.77 V→0.4 times;

3.73 V→0.5 times;

3.69 V→0.6 times;

3.67 V→0.7 times;

3.65 V→0.8 times;

3.60 V→0.9 times; and

3.30 V→1.0 time.

It should be noted that FIG. 5 shows how the capacitance rate changes relative to the discharging voltage.

In addition, the second weighting coefficient Y is determined, for example, in accordance with FIG. 6 as follows (a battery voltage immediately after completing charging→the second weighting coefficient Y):

3.60 V→0 times;

3.80 V→0.1 times;

3.84 V→0.2 times;

3.88 V→0.3 times;

3.92 V→0.4 times;

3.95 V→0.5 times;

3.98 V→0.6 times;

4.02 V→0.7 times;

4.05 V→0.8 times;

4.10 V→0.9 times; and

4.20 V→1.0 time.

It should be noted that FIG. 6 shows how the charging rate changes relative to the charging voltage.

Next, the function to count the number of cycles the rechargeable battery 32 has been charged and discharged (the method of calculating the life of the rechargeable battery) is described. The user sets the cellular telephone device 1 in the charger 100, and charges the rechargeable battery 32 until fully charged. In a case in which the cellular telephone device 1 is used until the rechargeable battery 32 runs down, it is possible to calculate the life of the rechargeable battery by simply counting the number of times charging and discharging for each time. However, in practice, in the cellular telephone device 1, charging may be suspended during the charging, and charging may be started even though the rechargeable battery 32 is in a fully charged state. In such cases, it is difficult to accurately count the number of times charging and discharging the cellular telephone device 1.

According to the present invention, in such a usage state, the aforementioned first weighting coefficient X and second weighting coefficient Y are used as count values of the number of cycles the rechargeable battery 32 has been charged and discharged, thereby making it possible to accurately count the number of cycles of charging and discharging.

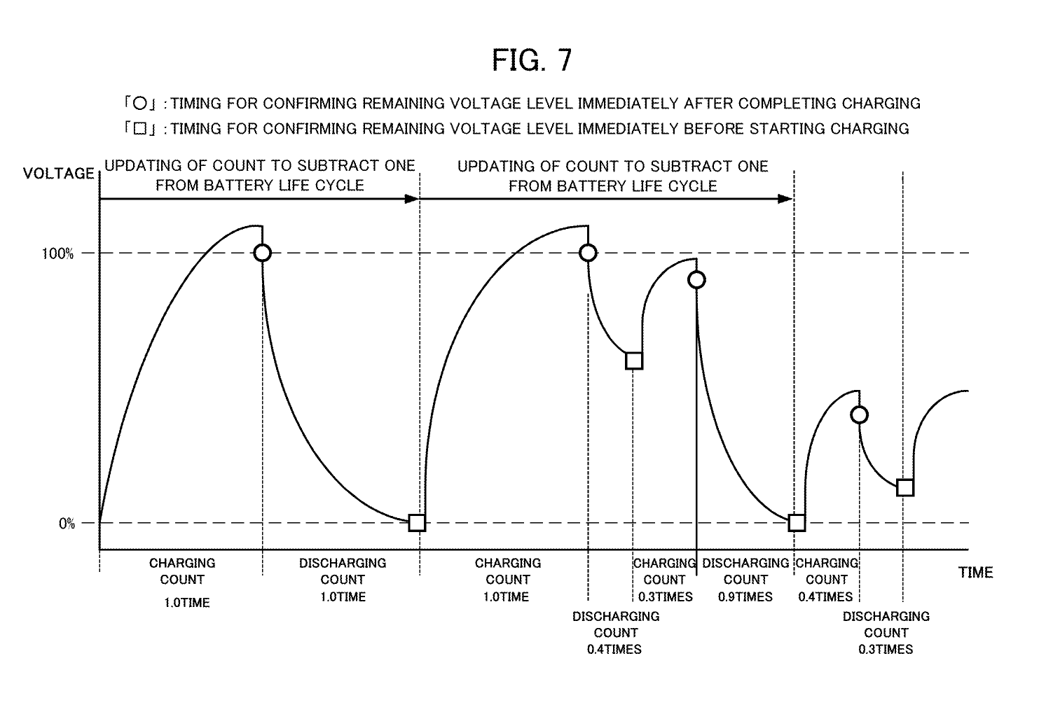

For example, according to the present invention, as shown in FIG. 7, the system IC 64 factors in the first weighting coefficient X and the second weighting coefficient Y, and counts the number of times charging and discharging. In addition, when a single cycle operation period has elapsed, the system IC 64 subtracts one from the number of times (for example, from 500 times) of a predetermined life of the rechargeable battery, and outputs this fact to the user by utilizing the display 21 and/or the sound output unit 22. It should be noted that a symbol “o” in FIG. 7 shows a timing for confirming the remaining voltage level when the cellular telephone device 1 is removed from the charger 100 (immediately after completing charging), and a symbol “□” in FIG. 7 shows a timing for confirming the remaining battery level when the cellular telephone device 1 is attached to the charger 100 (immediately before starting charging).

In this way, the number of cycles for which the rechargeable battery 32 according to the present invention has been charged and discharged will be calculated since the first time used, and in a case in which both charging and discharging or one of charging and discharging reaches a predetermined number of times (for example, 500 times) of the life of the rechargeable battery, it is determined that the life of the rechargeable battery has reached the end, and an output is carried out so as to prompt the user to perform replacement, etc. of the rechargeable battery 32.

It should be noted that, since the length of the cycle life of charging and discharging is different depending on a rechargeable battery to be employed, it is necessary to set the number of times charging to be adapted to the rechargeable battery to be employed.

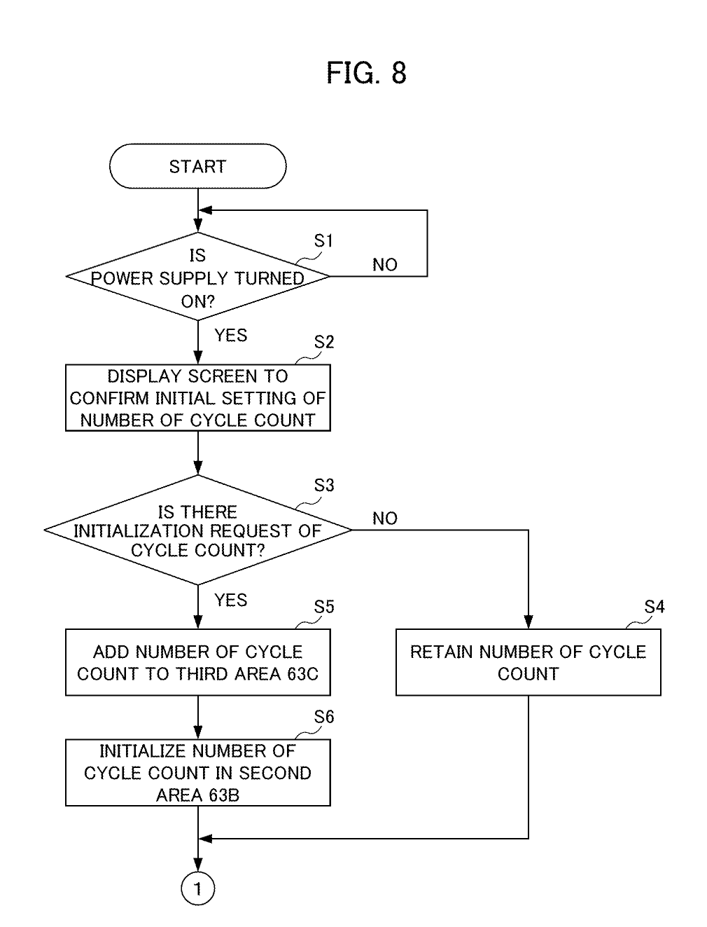

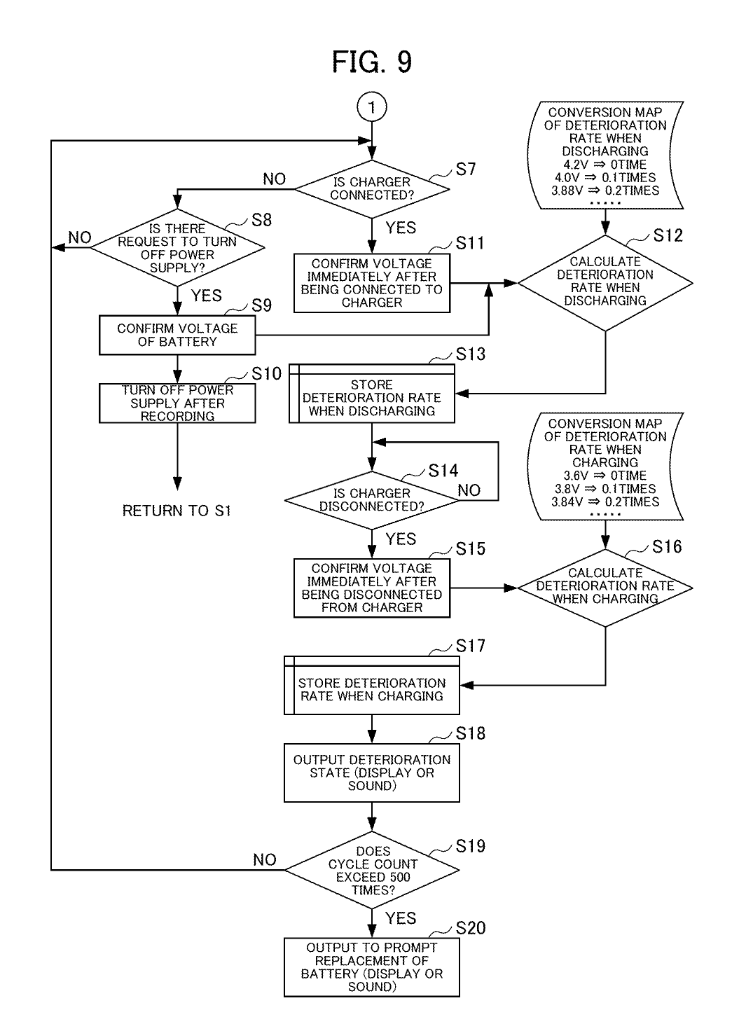

Next, the method of counting the number of cycles the rechargeable battery 32 has been charged and discharged, and the method of calculating the life of the rechargeable battery are described with reference to the flowcharts shown in FIGS. 8 and 9.

In Step S1, the system IC 64 determines whether the main power supply is in the ON state. In a case in which it has been determined that the main power supply is in the ON state (Yes), the processing advances to Step S2.

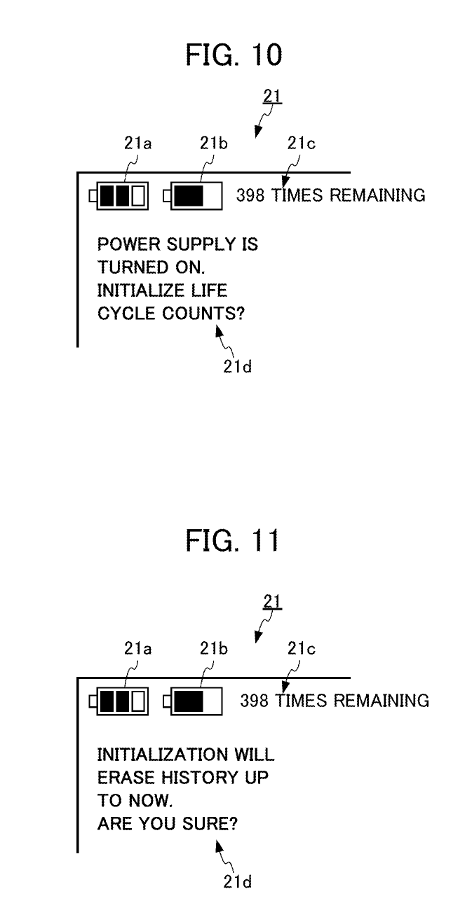

In Step S2, the system IC 64 performs display on the display 21 so as to confirm initial setting of the number of cycles (counts). Here, FIG. 10 shows a screen displayed on the display 21 in this step. A pictograph display 21a for roughly showing an ordinary remaining battery level, and a pictograph display 21b for accurately and clearly showing the life of the rechargeable battery are displayed in a row on an upper end portion of the display 21. Moreover, for example, a character display such as “398 times remaining” is displayed on a character display area 21c adjacent to the pictograph display 21b, so as to show how many remaining times the original charging capability can be exercised as the life of the rechargeable battery. In addition, in a predetermined area 21d of the display 21, a display such as, for example, “the power supply is turned on; initialize the count of cycle life?” can be performed, thereby prompting the user to select.

In Step S3, the system IC 64 determines whether there has been an initialization request of the count value of the number of cycles. In a case in which it has been determined that there has been an initialization request of the count value of the number of cycles (Yes), the processing advances to Step S5, and in a case in which it has been determined that there has not been an initialization request of the count value of the number of cycles (No), the processing advances to Step S4, Here, in a case in which it has been determined that there has been an initialization request of the count value of the number of cycles, a display as shown in FIG. 11 is displayed on the display 21. For example, a display such as “initialization will erase the history so far; are you sure?” is displayed on a predetermined area 21d of the display 21, thereby attracting the attention of the user.

In Step S4, the system IC 64 performs retention processing of the count value of the number of cycles. After completing the retention processing of the count value of the number of cycles, the processing advances to Step S7.

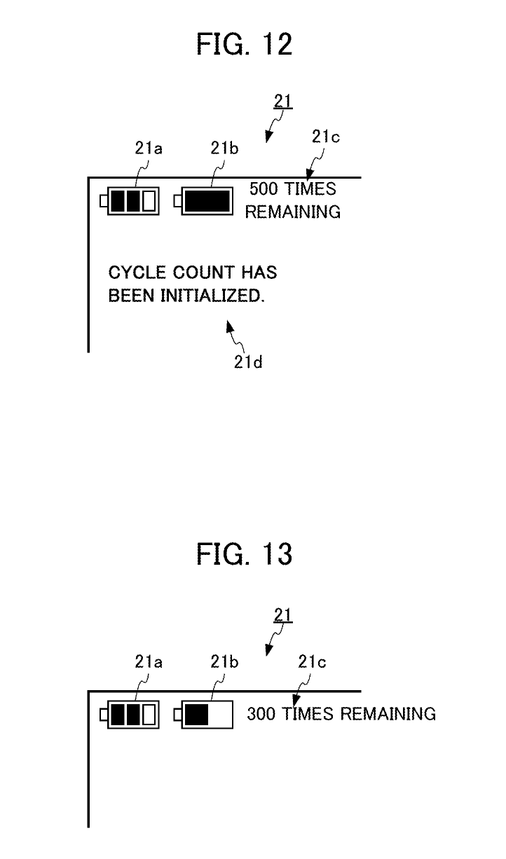

In Step S5, the system IC 64 adds a count value of the number of cycles to the third area 63C of the memory 63. Here, in a case in which the count value of the number of cycles has been added to the previous value that was stored in the third area 63C of the memory 63, a display as shown in FIG. 12 is performed on the display 21. In other words, in Step S5, the count value of the number of cycles, which has been retained in the second area 63B of the memory 63, is copied into the third area 63C. For example, the pictograph display 21b is displayed as a fully charged state, and a character display such as “500 times remaining” is displayed on the character display area 21c.

In Step S6, the system IC 64 initializes the count value of the number of cycles in the second area 63B of the memory 63. It should be noted that, as described above, the count value of the number of cycles stored in the third area 63C of the memory 63 remains without being erased by a user operation. Therefore, the battery life of the rechargeable battery 32 will continue to be accurately counted.

In Step S7, the system IC 64 determines whether the charger 100 is electrically connected. In a case in which it has been determined that the charger 100 is electrically connected (Yes), the processing advances to Step S11, and in a case in which it has been determined that the charger 100 is not electrically connected (No), the processing advances to Step S8.

In Step S8, the system IC 64 determines whether a request to turn off the power supply has been performed. In a case in which it has been determined that a request to turn off the power supply has been performed (Yes), the processing advances to Step S9, and in a case in which it has been determined that a request to turn off the power supply has not been performed (No), the processing advances to Step S7.

In Step S9, the system IC 64 confirms the battery voltage of the rechargeable battery 32. It should be noted that the confirmation of the battery voltage of the rechargeable battery 32 may be performed by a method similar to Step S12 to be described later.

In Step S10, the system IC 64 records the battery voltage of the rechargeable battery 32 in the memory 63, and subsequently turns off the main power supply.

In Step S11, the system IC 64 confirms the battery voltage of the rechargeable battery 32 immediately before being connected to the charger 100.

In Step S12, the system IC 64 calculates a deterioration rate when discharging, by factoring in the first weighting coefficient X that is determined according to FIG. 5.

In Step S13, the system IC 64 stores the deterioration rate when discharging, which was calculated in Step S12, into the memory 63.

In Step S14, the system IC 64 determines whether the charger 100 is electrically disconnected. In a case in which it has been determined that the charger 100 is electrically disconnected (Yes), the processing advances to Step S15, and in a case in which it has been determined that the charger 100 is not electrically disconnected (No), the processing repeats Step S14.

In Step S15, the system IC 64 confirms the battery voltage of the rechargeable battery 32 immediately after being disconnected from the charger 100.

In Step S16, the system IC 64 calculates a deterioration rate when charging, by factoring in the second weighting coefficient Y that is determined according to FIG. 6.

In Step S17, the system IC 64 stores the deterioration rate when charging, which was calculated in Step S16, into the memory 63.

In Step S18, the system IC 64 outputs information on the deterioration state (life of the rechargeable battery) to the user by utilizing the display 21 and/or the sound output unit 22. Here, a display as shown in FIG. 13 is displayed on the display 21.

In Step S19, the system IC 64 determines whether the count value of the number of cycles (the number of times related to the battery life) has exceeded a predetermined value (for example, 500 times). In a case in which it has been determined that the count value of the number of cycles has exceeded a predetermined value (Yes), the processing advances to Step S20, and in a case in which it has been determined that the count value of the number of cycles has not exceeded a predetermined value (No), the processing returns to Step S7.

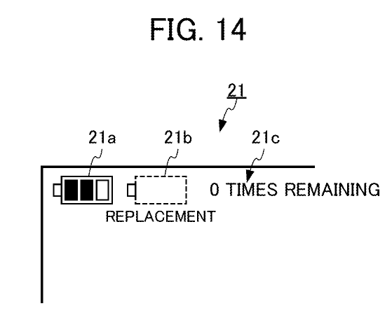

In Step S20, the system IC 64 carries out an output so as to prompt the user to perform replacement, etc. of the rechargeable battery 32, by utilizing the display 21 and/or the sound output unit 22. Here, as a display for prompting replacement of the rechargeable battery 32 on the display 21, for example, as shown in FIG. 14, the pictograph display 21b for accurately and clearly showing the life of the rechargeable battery is blinked, and a character “replacement” is blinked in the pictograph display 21b. In this way, the cellular telephone device 1 reminds the user of the fact that it has come time to replace the rechargeable battery 32.

As described above, in the cellular telephone device 1 according to the present invention, even in a case in which the rechargeable battery 32 is removed from the charger 100 before reaching a fully charged state, or in a case in which the rechargeable battery 32 is connected to the charger 100 in an almost fully charged state, the life of the rechargeable battery 32 is accurately measured. Moreover, since the cellular telephone device 1 clearly outputs the life of the rechargeable battery to the user, unlike conventional methods (such as measuring impedance or measuring an electric current), implementation through software control is possible without changing a hardware configuration. Therefore, the cellular telephone device 1 can accurately and clearly output the life of the rechargeable battery to the user with a simple configuration without increasing the cost.

In addition, according to the present invention, since the life of the rechargeable battery can be accurately and clearly recognized, operational comfort can be improved without causing the user himself/herself to determine life of the rechargeable battery.

Furthermore, according to the present invention, it is possible to avoid data loss, for example, due to failure of the rechargeable battery or sudden interruption of the electrical source as a result of using beyond the life of the rechargeable battery 32, and thus operational comfort can be improved.

In other words, in a case in which the cellular telephone device 1 is brought into a shop because the user has determined that the usable duration (charging/discharging capability) of the rechargeable battery 32 has deteriorated, then the third area 63C of the memory 63 is referred to. This makes it possible to determine whether the usable duration of the rechargeable battery 32 has deteriorated due to failure of the rechargeable battery 32, or the battery capability has decreased because the rechargeable battery 32 has been charged and discharged many times.

Moreover, although a configuration has been described in which a count value of the number of cycles of charging and discharging is stored in the memory 63 in the present embodiment, the present invention is not particularly limited to the present embodiment. For example, if the rechargeable battery 32 is configured with a memory area, a count value of the number of cycles of charging and discharging may be copied into such memory of the rechargeable battery 32 at any time. With such a configuration, even in a case in which only the rechargeable battery 32 is brought into a shop, a usage state can be determined by referring to the memory of the rechargeable battery 32.

In addition, according to the present invention, even in a case in which the user has performed an initialization operation of the count value of the number of cycles of charging and discharging the rechargeable battery 32, the count value of the number of cycles of charging and discharging the rechargeable battery 32 stored in the third area 63C of the memory 63 is not erased. Therefore, even if the user may provide a false report by any chance, such a situation can be overcome, and an appropriate action can be taken.

Furthermore, according to the present invention, the count value of the number of cycles of charging and discharging the rechargeable battery 32 stored in the third area 63C of the memory 63 is not erased by a user operation. Therefore, even if the user has inadvertently initialized the information stored in the second area 63B, when the device is brought into a shop (the enterprise side), the enterprise side copies the count value from the third area 63C into the second area 63B. In this way, the cellular telephone device 1 can restore the history of the count value of the number of cycles.

Moreover, according to the present invention, since the time for replacing the rechargeable battery 32 is output to the user only as information of a count value of the number of cycles, the user can clearly recognize the time for replacing the rechargeable battery 32.

In addition, according to the present invention, by providing a unique ID to the rechargeable battery 32, it is possible to correctly manage a count value of the number of cycles of a rechargeable battery of interest, and even in a case in which a plurality of rechargeable batteries 32 is provided, it is possible to manage each count value of the number of cycles of charging and discharging.

In the embodiment, although information on the rechargeable battery may be output to a display as well as a sound output unit, it is not limited thereto. Information on the rechargeable battery may be output to an externally connected monitor, and it may be output to a wirelessly connected external display unit via an antenna. In this way, in addition to the display and the sound output unit, an output unit may be an external connection terminal or a radio communication unit, and various forms thereof can be contemplated.

1. A portable electronic device, comprising:
an output unit that outputs a variety of information;
a storage unit that stores a weighting value for each voltage value;
a voltage measuring unit that measures, each time charging of a rechargeable battery that is mounted occurs, a voltage of the rechargeable battery; and
a control unit that extracts from the storage unit a weighting value corresponding to a voltage value measured via the voltage measuring unit, and that sequentially adds the weighting value thus extracted, thereby identifying information on a number of times charging, and storing the information in the storage unit,
wherein the control unit causes the output unit to output information on life of the rechargeable battery, based on the information on the number of times charging stored in the storage unit.

2. The portable electronic device according to claim 1, wherein the control unit measures, each time charging of the rechargeable battery is completed, a voltage of the rechargeable battery via the voltage measuring unit.

3. The portable electronic device according to claim 2, wherein the control unit measures, each time charging of the rechargeable battery is started, a voltage of the rechargeable battery via the voltage measuring unit.

4. The portable electronic device according to claim 3, wherein the weighting value corresponds to a large value when the voltage value is close to a full charge value, and the weighting value corresponds to a small value when the voltage value is close to a minimum operational voltage value.

5. The portable electronic device according to claim 4,
wherein the storage unit stores a predetermined value for indicating that the life of the rechargeable battery has reached an end, and
wherein the control unit identifies information on the life, based on a remaining level in the information on the number of times charging relative to the predetermined value.

6. The portable electronic device according to claim 5, wherein the control unit identifies information on the life as a remaining number of times for which charging is possible.

7. The portable electronic device according to claim 6, wherein the control unit detects a connection state of a charger that charges the rechargeable battery, and detects that the rechargeable battery has been mounted to the charger or that the rechargeable battery has been removed from the charger, based on the connection state, thereby determining that charging of the rechargeable battery has been started or completed.

8. The portable electronic device according to claim 5, wherein the output unit includes a display unit that displays the information on life of the rechargeable battery, based on the information on the number of times charging.

9. The portable electronic device according to claim 8, further comprising an operation unit that requests, by way of a predetermined operation, the control unit to initialize the information on the number of times charging stored in the storage unit,
wherein the storage unit includes an area that is not initialized, and
wherein, when an initialization request is performed by the operation unit, the control unit copies information, which is identical with the information on the number of times charging, into the area that is not initialized, and then initializes a display of the information on the life.

10. The portable electronic device according to claim 1,
wherein the storage unit stores a predetermined value for indicating that the life of the rechargeable battery has reached an end, and
wherein the control unit identifies information on the life, based on a remaining level in the information on the number of times charging relative to the predetermined value.

11. The portable electronic device according to claim 10, wherein the control unit identifies information on the life as a remaining number of times for which charging is possible.

12. The portable electronic device according to claim 3, wherein the control unit detects a connection state of a charger that charges the rechargeable battery, and detects that the rechargeable battery has been mounted to the charger or that the rechargeable battery has been removed from the charger, based on the connection state, thereby determining that charging of the rechargeable battery has been started or completed.

13. The portable electronic device according to claim 3, wherein the output unit includes a display unit that displays the information on life of the rechargeable battery, based on the information on the number of times charging.

14. The portable electronic device according to claim 3, further comprising an operation unit that requests, by way of a predetermined operation, the control unit to initialize the information on the number of times charging stored in the storage unit,
wherein the storage unit includes an area that is not initialized, and
wherein, when an initialization request is performed by the operation unit, the control unit copies information, which is identical with the information on the number of times charging, into the area that is not initialized, and then initializes a display of the information on the life.

15. A control method in a portable electronic device including a rechargeable battery, an output unit and a storage unit, the control method comprising the steps of:
measuring, each time charging of the rechargeable battery is started or completed, a voltage of the rechargeable battery;
extracting, from the storage unit, a weighting value corresponding to a voltage value thus measured;
sequentially adding the weighting value thus extracted;
identifying information on a number of times charging based on the weighting value thus added, and storing the information in the storage unit; and
causing the output unit to output information on life of the rechargeable battery, based on the information on the number of times charging stored in the storage unit.
